(19) United States
(12) Patent Application Publication
(10) Pub. No.: US 2014/0120478 A1
(43) Pub. Date: May 1, 2014

(54) TECHNIQUES FOR PATTERNING RESIST

(71) Applicant: VARIAN SEMICONDUCTOR EQUIPMENT ASSO, Glouecester, MA (US)

(72) Inventor: Armah M. Kpissay, Beverly Farms, MA (US)

(73) Assignee: VARIAN SEMICONDUCTOR EQUIPMENT ASSOCIATES, INC., Gloucester, MA (US)

(21) Appl. No.: 13/661,932

(22) Filed: Oct. 26, 2012

(51) Int. Cl. G03F 7/20

(52) U.S. Cl. 430/326

(57) ABSTRACT

A technique for patterning a substrate is disclosed. In accordance with one exemplary embodiment, the technique may be realized as a method for patterning a substrate. The method may comprise: providing a resist on the substrate; introducing one or more species of impurities into the resist; selectively exposing a first portion of the resist to radiation while a second portion of the resist is not exposed to the radiation; exposing the resist to a developer and removing the first portion of the resist exposed to the radiation from the substrate; and exposing the resist at a temperature higher than a room temperature but lower than glass transition temperature of the resist.

### PRIORITY

This application claims priority to U.S. Provisional Patent Application Ser. No. 61/564,574, filed on Nov. 29, 2011, entitled “Techniques For Patterning A Substrate.” The entire specification of U.S. Provisional Patent Application Ser. No. 61/564,574, is incorporated herein by reference.

### FIELD

The present disclosure relates generally to techniques for substrate processing, more particularly to techniques for patterning resist formed on a substrate.

### BACKGROUND

A patterning process is one of many processes used in manufacturing devices, including integrated circuit (IC) devices. Generally, it is used to define features in the devices. It plays an important role as the devices and the features contained therein continue to become smaller.

One of the patterning processes used in device manufacturing is a photolithographic process. In this process, a desired pattern is formed on a mask. The pattern is then transferred onto the substrate via a photoresist. For example, a layer of photoresist is deposited on the substrate. Thereafter, a mask with an aperture arranged in a desired pattern is disposed above the photoresist. Radiation from a light source above the mask is then directed toward the substrate, and the pattern of the aperture of the mask is imaged on the photoresist. Thereafter, the photoresist is exposed to a developer solution, such as tetramethyl ammonium hydroxide. As the radiation exposure causes the photoresist to become soluble to the developer solution, a portion of the photoresist exposed to the radiation is dissolved and removed from the substrate. Meanwhile, another portion not exposed to the radiation may remain insoluble and remain on the substrate as the resist structures. The remaining resist structures, which may be arranged in a desired pattern, may be baked and further hardened. These resist structures are used as a mask for subsequent, for example, etching process, where the pattern of the resist structure is transferred onto the substrate.

As the process is a pattern transferring process, any defect in the mask or the resist structures may ultimately be transferred onto the substrate. In the conventional photolithographic processes, excessive line edge roughness (LER) and line width roughness (LWR) are found. Such defects may be transferred into the substrate resulting in trenches or features with rough edges and/or non-uniform widths. And these defects may ultimately lead to devices with non-uniform performance or to defective devices.

Accordingly, a new process that limits or reduces the LER and LWR in photolithographic process is needed.

### SUMMARY

Techniques for patterning resist are disclosed. In accordance with one exemplary embodiment, the technique may be realized as a method for patterning a substrate. The method may comprise: providing a resist on the substrate; introducing one or more species of impurities into the resist; selectively exposing a first portion of the resist to radiation while a second portion of the resist is not exposed to the radiation; exposing the resist to a developer and removing the first portion of the resist exposed to the radiation from the substrate; and exposing the resist at a temperature higher than a room temperature but lower than glass transition temperature of the resist.

In accordance with other aspects of this particular exemplary embodiment, the one or more species of impurities may be introduced into the resist prior to the exposing the resist to a developer.

In accordance with further aspects of this particular exemplary embodiment, the one or more species of impurities may be introduced into the resist prior to the selectively exposing the first portion of the resist to the radiation.

In accordance with additional aspects of this particular exemplary embodiment, the one or more species of impurities may be introduced into the resist after the selectively exposing the first portion of the resist to the radiation.

In accordance with further aspects of this particular exemplary embodiment, the impurities may contain one or more species chosen from a group consisting of nitrogen (N), carbon (C), silicon (Si), hydrogen (H), oxygen (O), and fluorine (F).

In accordance with other aspects of this particular exemplary embodiment, the impurities may be introduced in a form of ions using ion implantation process.

In accordance with further aspects of this particular exemplary embodiment, the exposing the resist at a temperature higher than a room temperature but lower than glass transition temperature of the resist may occur during the ion implantation process.

In accordance with additional aspects of this particular exemplary embodiment, the exposing the resist at a temperature higher than a room temperature but lower than glass transition temperature of the resist may occur after the ion implantation process.

In accordance with other aspects of this particular exemplary embodiment, the exposing the resist at a temperature higher than a room temperature but lower than glass transition temperature of the resist may occurs prior to the ion implantation process.

In accordance with additional aspects of this particular exemplary embodiment, the exposing the resist at a temperature higher than a room temperature but lower than glass transition temperature of the resist occurs prior to the exposing the resist to a developer.

In accordance with further aspects of this particular exemplary embodiment, the exposing the resist at a temperature higher than a room temperature but lower than glass transition temperature of the resist occurs prior to the exposing the resist to the radiation.

In accordance with another exemplary embodiment, the technique may be realized as a method for patterning a substrate. The method may comprise: providing a resist on the substrate; introducing one or more species of impurities into the resist; selectively exposing a first portion of the resist introduced with impurities to radiation while a second portion of the resist introduced with impurities is not exposed to the radiation; exposing the resist to a developer and removing the first portion of the resist exposed to the radiation from the substrate.

In accordance with other aspects of this particular exemplary embodiment, the impurities may contain one or more species chosen from a group consisting of nitrogen (N), carbon (C), silicon (Si), hydrogen (H), oxygen (O), and fluorine (F).

In accordance with further aspects of this particular exemplary embodiment, the impurities may be negative ions.

In accordance with additional aspects of this particular exemplary embodiment, the impurities may be introduced in a form of ions using ion implantation process.

In accordance with further aspects of this particular exemplary embodiment, the method may further comprise: exposing the resist at a temperature higher than a room temperature but lower than a glass transition temperature of the resist.

In accordance with additional aspects of this particular exemplary embodiment, the impurities may be introduced in a form of ions using ion implantation process and where the exposing the resist at the temperature higher than the room temperature but lower than the glass transition temperature of the resist may occur during the ion implantation process.

In accordance with further aspects of this particular exemplary embodiment, the impurities may be introduced in a form of ions using ion implantation process and where the exposing the resist at the temperature higher than a room temperature but lower than the glass transition temperature of the resist occurs after the ion implantation process.

In accordance with another exemplary embodiment, the technique may be realized as a method for patterning a substrate. The method may comprise: providing a resist on the substrate; introducing one or more species of impurities into the resist, wherein the impurities contains at least one of nitrogen (N), hydrogen (H), oxygen (O), and fluorine (F); selectively exposing a first portion of the resist introduced with impurities to radiation while a second portion of the resist introduced with impurities is not exposed to the radiation; and exposing the resist to a developer and removing the first portion of the resist exposed to the radiation from the substrate.

The present disclosure will now be described in more detail with reference to exemplary embodiments thereof as shown in the accompanying drawings. While the present disclosure is described below with reference to exemplary embodiments, it should be understood that the present disclosure is not limited thereto. Those of ordinary skill in the art having access to the teachings herein will recognize additional implementations, modifications, and embodiments, as well as other fields of use, which are within the scope of the present disclosure as described herein, and with respect to which the present disclosure may be of significant utility.

### BRIEF DESCRIPTION OF THE DRAWINGS

In order to facilitate a fuller understanding of the present disclosure, reference is now made to the accompanying drawings, in which like elements are referenced with like numerals. These drawings should not be construed as limiting the present disclosure, but are intended to be exemplary only.

FIG. 1A-1H illustrate an exemplary method of patterning a substrate according to one embodiment of the present disclosure.

FIG. 2A-2H illustrate another exemplary method of patterning a substrate according to another embodiment of the present disclosure.

FIG. 3A-3H illustrate another exemplary method of patterning a substrate according to another embodiment of the present disclosure.

### DETAILED DESCRIPTION

The present disclosure will now be described in more detail with reference to particular embodiments thereof as shown in the accompanying drawings. While the present disclosure is described below with reference to particular embodiments, it should be understood that the present disclosure is not limited thereto. For example, the present disclosure includes a step in which impurities are added to photoresist or developed resist structure. For clarity and simplicity, the present disclosure will focus on adding the impurities in a form of ions via ion implantation process. However, those of ordinary skill in the art will recognize that the impurities need not be introduced via ion implantation process. The impurities may be introduced via other processes including thermal diffusion process, gas immersion laser doping (GILD) process, and other doping or impurities introducing processes, all of which are not precluded in the present disclosure.

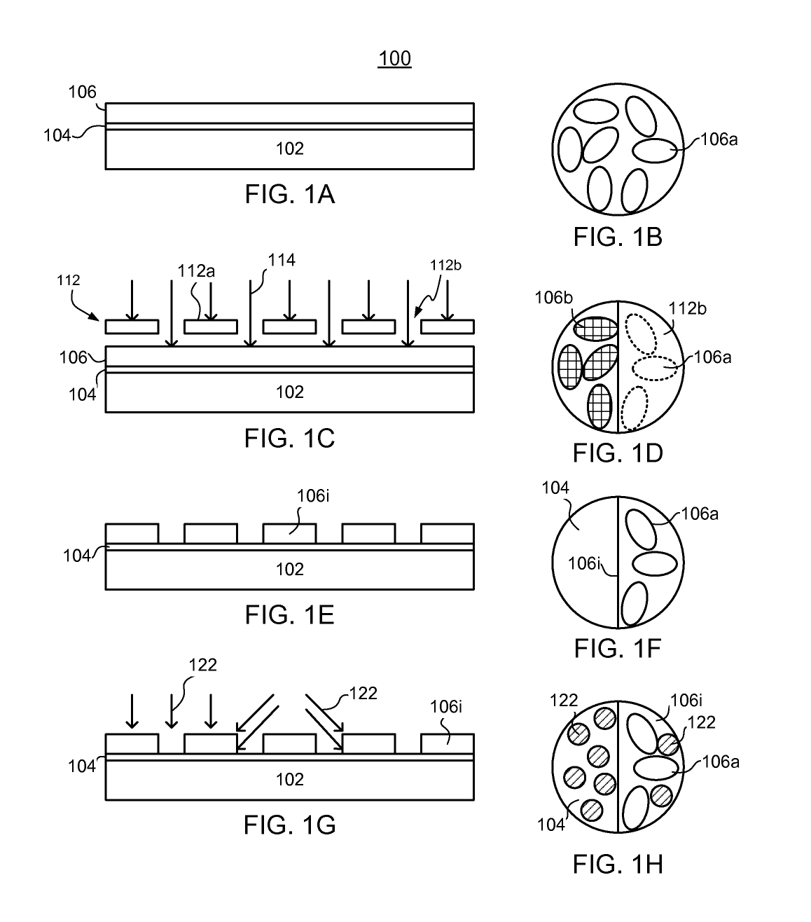

Referring to FIG. 1A-1H, there is shown a method 100 for patterning a substrate according to one embodiment of the present disclosure. FIG. 1A, 1C, 1E, and 1G illustrate side views of the substrate 102 and the process performed thereon. FIGS. 1B, 1D, 1F, and 1H illustrate top views of the substrate 102 during the steps shown in FIG. 1A, 1C, 1E, and 1G, respectively.

In the present embodiment, a substrate 102 may be coated with a layer of resist 106, as illustrated in FIG. 1A. In the present disclosure, a bottom anti-reflective coating (BARC) layer 104 may optionally be provided between the substrate 102 and the resist 106. The resist 106, in the present disclosure, is not limited to a particular type of resist 106. For clarity and simplicity, the present disclosure will focus on using positive polymer based photoresist with pendant acid sensitive group containing, among others, a small amount (e.g. about 5-10 weight percent) of onium salt or photo acid generator (PAG) 106a. Because of their ionic character, PAG 106a may aggregate in an otherwise hydrophobic resist matrix 106.

After depositing the resist 106, the resist 106 may undergo an exposure step shown in FIG. 1C. In this exposure step, a mask 112 is positioned between the resist 106 and a light source (not shown), and the radiation 114 from the light source is directed toward the resist 106. In the present embodiment, the light source may be an ultraviolet (UV) light source emitting UV radiation in the range of about 193 nm. However, those of ordinary skill in the art will recognize that radiation with other wavelengths may also be used.

The mask 112 may comprise one or more transparent areas 112a, such as apertures, defined by one or more opaque areas 112b. Such transparent areas 112a may be arranged in a desired pattern. As shown in FIG. 1C, the radiation 114 may pass through the transparent areas 112a, but not through the opaque areas 112b. In the process, the pattern of the apertures may be imaged on the resist 106, and one or more regions of the resist 106 are exposed to the radiation 114. This exposure step is followed by a resist development step, where the resist 106 is exposed to developer or alkaline solution, and portions of the resist 106 exposed to the radiation is removed. After the resist development step, one or more resist structure 106i may form on the substrate 102, as shown in FIG. 1E. If included, portions of the BARC layer 104 may be exposed through the gap between the resist structures 106i.

During the exposure step that precedes the resist development step, PAG 106a within the resist 106 may be activated, and a small amount of acid may be generated. This acid may catalyze the deprotection of the pendant carboxylic acid groups in the resist 106 when the resist 106 is subsequently baked. The acid, however, is not consumed during the deprotection reaction. Instead, the acid continues to deprotect additional pendant groups. Through this chemical amplification process, solubility of the portions of the resist 106 exposed to the radiation 114 to the developer solution or alkaline solution may increase. The portions may dissolve and be removed from the substrate 102. The area of the resist 106 not exposed to the radiation 114, however, may remain insoluble to the developer or alkaline solution and remain on the substrate 102 after the resist development step.

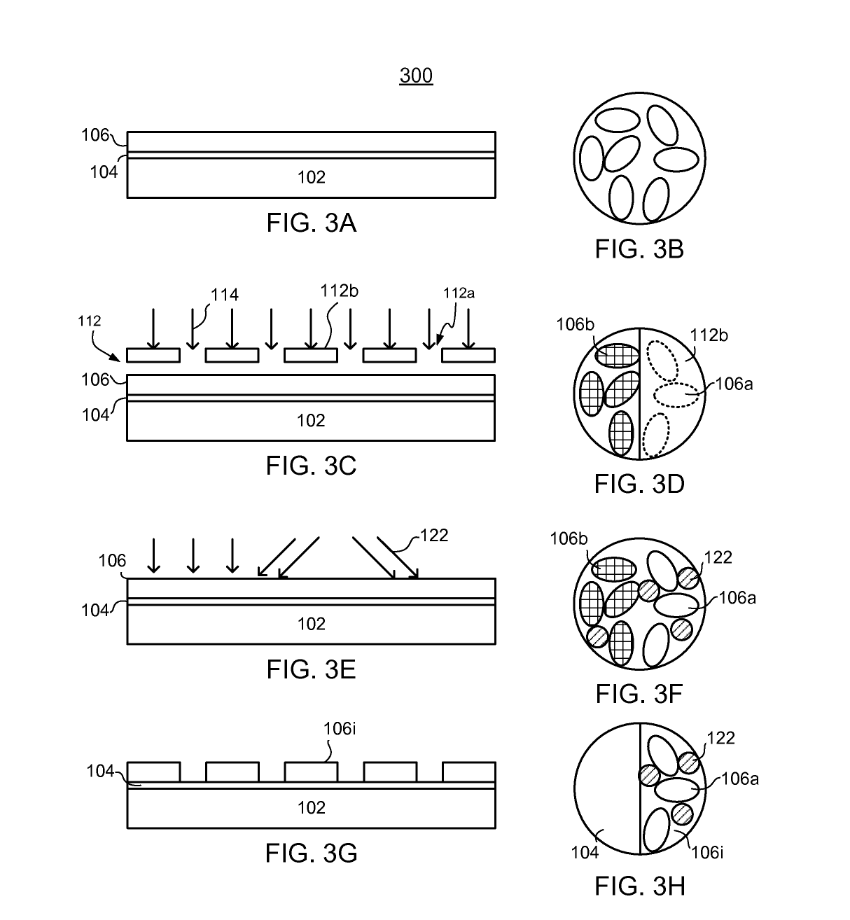

In the present embodiment, the resist development step may be followed by impurities introduction step, as shown in FIG. 3E. In this step, impurities are introduced into the resist structure 106i remaining on the substrate 102 and, if included, the exposed portion of the BARC layer 104. In the present embodiment, the impurities may preferably be introduced in a form of ions 122. The ions 122 may be directed toward the resist structure 106i preferably at one or more angles, as shown in FIG. 1, and implanted into the vertically and horizontally extending surfaces of the resist structure 106i. In the present embodiment, the energy by which the ions 122 are introduced may be low, preferably ranging between about 50 eV to about 2.0 KeV. However, the present disclosure does not preclude implanting ions at other energies. As a result, the ions 122 may be disposed in the resist structure 106i, and, if included, the exposed portion of the BARC layer 104, as shown in FIG. 1H.

In the present disclosure, various species of the impurities may be introduced. The preferred species may include species with high chemical potential. For example, the ions 122 that may be implanted may be those capable of forming sub-molecular interactions such as, for example, hydrogen/dangling bonds, n-n*, sp³-sp³, through space or hydrophobic interactions with the resist polymer or with other ions. Specific examples may include atomic or molecular species containing nitrogen (N), carbon (C), silicon (Si), hydrogen (H), oxygen (O), and fluorine (F). However, other species are not precluded in the present disclosure. When introduced, only one of the foregoing species may be implanted in the present embodiment. In other embodiments, two or more of the foregoing species may be implanted, simultaneously or at different times. Moreover, the ions 122, in the present disclosure may be positive or negative ions.

If the species of the ions 122 is N or N containing species, the ions 122 implanted in to the resist structure 106i may move away from the surface as a result of hydrophobic interactions. The introduced N may then undergo sub-molecular interactions (e.g. hydrogen bonds or n-n*) with O and/or H atoms in the resist structure 106i, and become embedded in the resist structure 106i. In the process, stable N-N interactions may occur, and the density of the resist structure 106i may increase. With increased density, the etch resistance and the strength or hardness of the resist structures 106i may improve. The resist structure 106i may be able to withstand other processes performed subsequently, including subsequently performed plasma-based pattern transferring processes. Accordingly, the edges of the resist structure 106i will be less likely to be degraded during the pattern transfer, and reduction in LER and LWR may result.

If the species introduced into the resist structure 106i is C or C containing species, the species may stabilize with the polymer in the resist structure 106i by through-space sp³ interactions. In addition, the species may also increase the strength or hardness and etch resistance of the resist structure 106i. If the species introduced into the resist structure 106i is Si or Si containing species, the etch resistance and the strength or hardness of the resist structure 106i may improve even further. Meanwhile, the species containing F, if introduced, may migrate away from the surface and be embedded in the resist structure 106i as a result of hydrophobic interactions. The density of the resist structure 106i, in the process, may increase, and additional improvement to LER and LWR may be observed.

During or after the impurities introduction step, the resist structure 106i may undergo a thermal treatment step. During this thermal treatment step, the temperature of the resist structure 106i (Tᵣₛ) may be maintained at a temperature greater than the room temperature (Tᵣₘ), but less than the glass transition temperature (T_{g}) of the resist structure 106i. With the thermal treatment, the polymer chains within the resist structure 106i may coalesce around or move away from the impurities, and the density of the resist structure 106i may increase. The resist structure 106 may also experience reduced buckling that it may otherwise experience during an annealing or other high temperature thermal treatment steps, thereby strengthening and enhancing the sub-molecular interactions discussed above. This may improve the hardness or strength of the resist of the resist structure 106i and, thus, its etch resistance. With this improved etch resistance, the fidelity of pattern may be maintained. In other words, the thermal treatment will help adjust the LER.

In the present disclosure, the thermal treatment below the T_{g} is preferred as such a treatment may limit the fluidity of the resist structure 106i. More fluid resist structures 106i are not preferable, as the fidelity of the pattern may be affected. In the present embodiment, this thermal process step may be performed during the ion implantation step. Alternatively, the resist structure 106i may undergo a separate thermal treatment process after the ion implantation step.

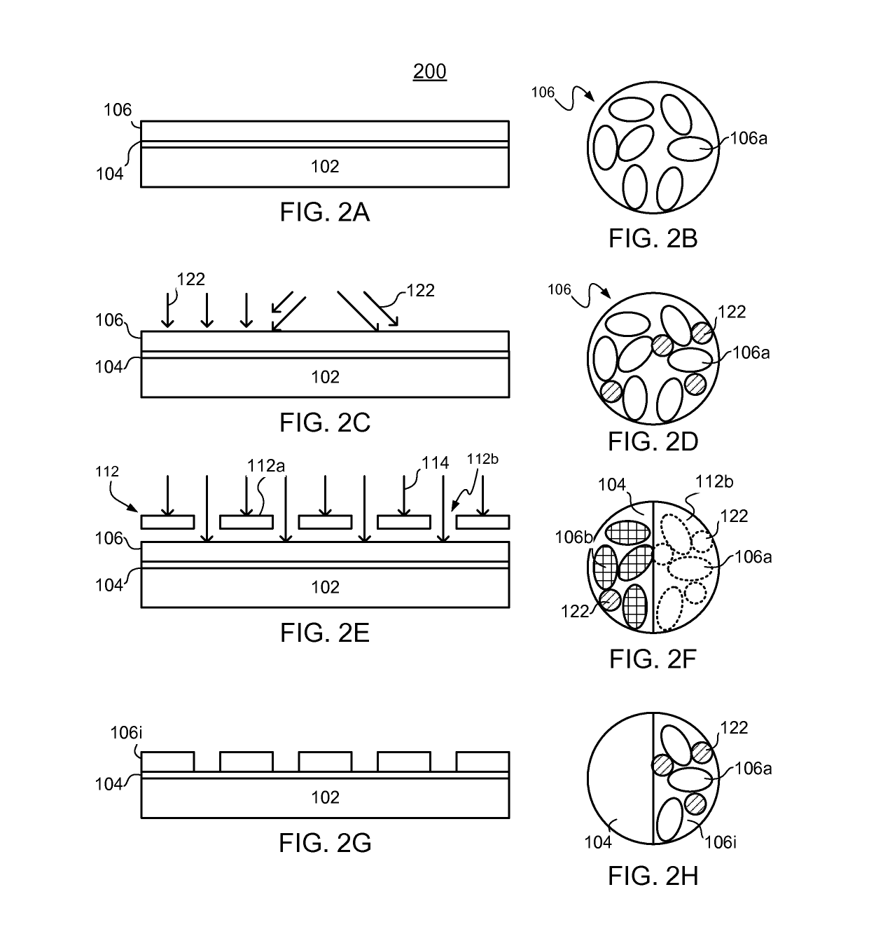

In the present embodiment, implanting ions after forming the resist structure 106i may provide additional benefits. In addition to the resist structure 106i, the ions 122 may also be implanted and mechanically weaken the BARC layer 104 (see FIG. 1G). In the process, the etch rate of the BARC layer 104 may be increased, and less time may be necessary in a subsequent etch step to etch the BARC layer 104. When the overall etch time is reduced, the degradation of edges of the resist structure 106i by the etchant used during the etch step is reduced. As such, the rate by which LER may occur may also be reduced. Referring to FIG. 2A-2H, there is shown another exemplary method 200 for patterning a substrate according to another embodiment of the present disclosure. FIG. 2A, 2C, 2E, and 2G illustrate side views of the substrate 102 and the process performed thereon. FIG. 2B, 2D, 2F, and 2H respectively illustrate the plan views of the substrate 102 during the steps shown in FIG. 2A, 2C, 2E, and 2G. Those of ordinary skill in the art will recognize that several steps and features included in the in the previous embodiment shown in FIG. 1A-1H is also included in the present embodiment. Detailed descriptions of such repeating steps and features may be omitted. As such, the method of the present embodiment should be understood in relation to the method shown in FIG. 1A-1H. In addition, several specific steps, including the thermal treatment step, disclosed in the prior embodiment may be included in the present embodiment even if detailed descriptions of the repeating steps are missing.

In the present embodiment, the substrate 102 may be coated with the layer of resist 106, as illustrated in FIG. 2A. Optionally, a (BARC) layer 104 may also be provided between the substrate 102 and the resist 106. As illustrated in FIG. 2B, the resist 106 may comprise PAG 106.

In the present embodiment, the impurities may be introduced into the resist 106. Much like the prior embodiment, however, the impurities are preferably introduced as the ions 122 via the ion implantation process shown in FIG. 2C. Unlike the prior embodiment, however, the impurities, in the form of ions 122, are introduced prior to the resist exposure step, and prior to forming the resist structure 106i. Although various species may be contained in the ions 122 and introduced as the impurities, the preferred species may include species with high chemical potential. Specific examples of the species may be those containing C, F, O, H, and Off, or their combination. In addition, the ions 122 may be introduced at one or more angles, at one or more energies ranging between about 50 eV to about 2.0 KeV.

The exposure step, as shown in FIG. 2E, may follow the impurities introducing step. Thereafter, the development step, as shown in FIG. 2G, may be performed to form the resist structure 106i. Those of ordinary skill in the art will recognize that the thermal treatment step disclosed in the earlier embodiment may also be performed. If performed, the thermal treatment step may be performed during or after the impurities introducing step.

In the present embodiment, the impurities introduced as ions 122 may collide with PAG 106a in the resist 106 and reduce the mean free path of the activated PAG 106b during chemical amplification. This reduction may result in the limiting the activated PAG 106b from diffusing into the portions of the resist 106 not exposed to the radiation 114. Accordingly, chemical amplification may be limited to the portions of the resist 106 exposed to the radiation 114, as it is more entropically favorable for the acid to act in the exposed than the unexposed areas. The ions 122 may also cause a small reduction in the radius of the polymer chains. This decrease may also reduce the diffusion of the acid and the acid-catalyzed deprotection of pendant groups in the portions of the resist not exposed to the radiation 114. By limiting the acid-catalyzed deportection of the pendant groups in the portions of the resist not exposed to the radiation 114, LER may be reduced. The resist structures 106i with straight, well defined edges may be obtained during the development stage. Thus, the impurities may induce thermodynamic asymmetry during the chemical amplification step.

If the ions 122 is C or C containing species, the ions 12 may increase the etch resistance of the resist 106 to reduce LER or LWR. If the ions 122 are F ions or F containing ions, the impurities may be embedded within the resist 106 due to the hydrophobic nature of the impurities, and the density of the resist 106 may increase prior to the exposure step. This increase in the density may improve the structural hardness or strength of the resist 106. As a result, LER that may otherwise occur during the development step may be reduced.

If the impurities or the ions 122 contain negative OH⁻, the impurities will dissipate their charges and may generate infinitesimal charge as they are introduced into the resist 106. This charge may inhibit the developer anion from being transported into the areas of the resist 106 not exposed to the radiation 114. The developer anions will however dissolve the carboxylic acids in the portions of the resist 106 exposed to the radiation 114 as deprotonation in those portions are more entropically favored. Thus, negative OH⁻ may induce thermodynamic asymmetry during the resist development step, and LER or LWR may be reduced.

Referring to FIG. 3A-3H, there is shown a method 300 for patterning a substrate according to another embodiment of the present disclosure. FIG. 3A, 3C, 3E, and 3G illustrate side views of the substrate 102 and the process performed thereon. FIG. 3B, 3D, 3F, and 3H illustrate top views of the substrate 102 during steps shown in FIG. 3A, 3C, 3E, and 3G, respectively. Those of ordinary skill in the art will recognize that several steps and features included in the in the previous embodiments shown in FIG. 1A-1H and 2A-2H are also included in the present embodiment. Detailed descriptions of such repeating steps and features may be omitted. As such, the method of the present embodiment should be understood in relation to the methods shown in FIG. 1A-1H and 2A-2H. In addition, several specific steps, including the thermal treatment step, disclosed in the prior embodiment may be included in the present embodiment even if detailed descriptions of the repeating steps are missing.

In the present embodiment, the substrate 102 may be coated with the layer of resist 106, as illustrated in FIG. 3A. Optionally, a (BARC) layer 104 may also be provided between the substrate 102 and the resist 106. As illustrated in FIG. 3B, the resist 106 may comprise PAG 106. After preparing the substrate 102 with the resist 106 coated thereon, the exposure step shown in FIG. 3C and 3D may take place. As illustrated in FIG. 3D, PAG 106a in the portions of the resist 106 exposed to the light are activated to form the activated PAG 106b, and the solubility of the resist 106 in such portions may be altered. After the exposure step, impurities are introduced into the resist 106. Similar to the earlier embodiments, the impurities may be introduced as ions 122, as shown in FIG. 3E and 3F. If introduced via ion implantation process, the ions 122 may be introduced at one or more energies ranging between about 50 eV to about 1.5 KeV. Moreover, the ions 122 may be introduced at one or more angles. As noted above, various species may be introduced as the impurities. However, the preferred species in the present embodiment may include species high chemical potential. Specific examples of the species may include Si, C, O, H, and OH⁻ species, or their combination.

The impurity introducing step shown in FIG. 3E may be followed by the development step shown in FIG. 3G. Much like the prior embodiment, the resist 106 is exposed to the developer or alkaline solution during the step. The portions of the resist 106 exposed to the radiation 114 may be removed from the substrate 102. As a result, the resist structures 106i may form as shown in FIG. 3G and 3H.

As noted above, introducing the impurities containing C may increase the etch resistance of the resist 106 and minimize LER and LWR. Meanwhile, introducing impurities containing Si may increase the etch resistance of the resist 106 to a greater extent. Although not precluded in the present disclosure, Si, if introduced, may preferably be introduced after the exposure step. Introduction of the Si prior to the exposure step may not be preferable due to the species' high optical adsorption. The high optical adsorption of Si may induce the resulting resist 106 to increase its reflectivity and reduce the ability of the radiation 114 to increase the solubility of the resist. If OH negative ions are introduced, the ions may induce thermodynamic asymmetry during the resist development step by inhibiting developer anion transport into the unexposed areas. As such, LER or LWR may be improved.

Herein, techniques for patterning resist on a substrate are disclosed. The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Further, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

1. A method for patterning a substrate, the method comprising:
providing a resist on the substrate;
introducing one or more species of impurities into the resist;
selectively exposing a first portion of the resist to radiation while a second portion of the resist is not exposed to the radiation;
exposing the resist to a developer and removing the first portion of the resist exposed to the radiation from the substrate; and
exposing the resist at a temperature higher than a room temperature but lower than glass transition temperature of the resist,.
wherein the one or more species of impurities are introduced into the resist after the selectively exposing the first portion of the resist to the radiation and after exposing the resist to the developer.

2-4. (canceled)

5. The method according to claim 1, wherein the impurities contain one or more species chosen from a group consisting of nitrogen (N), carbon (C), silicon (Si), hydrogen (H), oxygen (O), hydroxide (OH) and fluorine (F).

6. The method according to claim 5, wherein the impurities are introduced in a form of ions using ion implantation process.

7. The method according to claim 6, wherein the exposing the resist at a temperature higher than a room temperature but lower than glass transition temperature of the resist occurs during the ion implantation process.

8. The method according to claim 6, wherein the exposing the resist at a temperature higher than a room temperature but lower than glass transition temperature of the resist occurs after the ion implantation process.

9. (canceled)

10. The method according to claim 6, wherein the exposing the resist at a temperature higher than a room temperature but lower than glass transition temperature of the resist occurs prior to the exposing the resist to a developer.

11. A method for patterning a substrate, the method comprising:
providing a resist on the substrate;
introducing one or more species of impurities into the resist;
selectively exposing a first portion of the resist introduced with impurities to radiation while a second portion of the resist introduced with impurities is not exposed to the radiation; and
exposing the resist to a developer and removing the first portion of the resist exposed to the radiation from the substrate, wherein the one or more species of impurities are introduced at one or more angles and at one or more energies ranging between 50 eV and 2.0 KeV.

12. The method according to claim 11, wherein.

13. The method according to claim 12, wherein the impurities are negative ions.

14. The method according to claim 12, wherein the impurities are introduced in a form of ions using ion implantation process.

15. The method according to claim 11, further comprising:
exposing the resist at a temperature higher than a room temperature but lower than a glass transition temperature of the resist.

16. The method according to claim 15, wherein the impurities are introduced in a form of ions using ion implantation process and wherein the exposing the resist at the temperature higher than the room temperature but lower than the glass transition temperature of the resist occurs during the ion implantation process.

17. The method according to claim 15, wherein the impurities are introduced in a form of ions using ion implantation process and wherein the exposing the resist at the temperature higher than a room temperature but lower than the glass transition temperature of the resist occurs after the ion implantation process.

18. A method for patterning a substrate, the method comprising:
providing a resist on the substrate;
introducing one or more species of impurities into the resist, wherein the impurities contain at least one of nitrogen (N), hydrogen (H), oxygen (O), and fluorine (F);
selectively exposing a first portion of the resist introduced with impurities to radiation while a second portion of the resist introduced with impurities is not exposed to the radiation; and
exposing the resist to a developer and removing the first portion of the resist exposed to the radiation from the substrate, wherein the one or more species of impurities are introduced at one or more energies ranging between 50 eV and 1.5 KeV.
